(19) United States
(12) Patent Application Publication
(10) Pub. No.: US 2012/0064678 A1
(43) Pub. Date: Mar. 15, 2012

(54) MANUFACTURING METHOD OF THIN FILM TRANSISTOR ARRAY PANEL

(76) Inventors: Byeong-Jin LEE, Yongin-si (KR); Yu-Gwang Jeong, Yongin-si (KR); Dong-Ju Yang, Seoul (KR); Bong-Kyun Kim, Hwaseong-si (KR); Hong-Sick Park, Suwon-si (KR); Byeong-Beom Kim, Suwon-si (KR); Sang-Gab Kim, Seoul (KR); Ji-Young Park, Hwaseong-si (KR); Jean-Ho Song, Yongin-si (KR); Ki-Yeup Lee, Yongin-si (KR); Shin-Il Choi, Hwaseong-si (KR)

(21) Appl. No.: 13/069,070

(22) Filed: Mar. 22, 2011

(30) Foreign Application Priority Data
Sep. 14, 2010 (KR) 10-2010-0090010

(51) Int. Cl. H01L 21/336

(52) U.S. Cl. 438/158; 257/E21.409

(57) ABSTRACT

A method for manufacturing a TFT array panel includes forming a photosensitive film pattern with first and second parts in first and second sections on a metal layer, etching the metal layer of a third section using the film pattern as a mask to form first and second metal patterns, etching the film pattern to remove the first part, etching first and second amorphous silicon layers of the third section using the second part as a mask to form an amorphous silicon pattern and a semiconductor, etching the first and second metal patterns of the first section using the second part as a mask to form a source electrode and a drain electrode including an upper layer and a lower layer, and etching the amorphous silicon pattern of the region corresponding to the first section by using the second part as a mask to form an ohmic contact.

### CROSS-REFERENCE TO RELATED APPLICATION

This application claims priority to Korean Patent Application No. 10-2010-0090010 filed in the Korean Intellectual Property Office on Sep. 14, 2010, the disclosure of which is incorporated by reference herein.

### BACKGROUND OF THE INVENTION

(a) Technical Field

The present disclosure relates to a method of manufacturing a thin film transistor array panel.

(b) Discussion of Related Art

A liquid crystal display (LCD) is a flat panel display that includes two substrates with electrodes foamed thereon and a liquid crystal layer interposed between the two substrates. In the LCD, a voltage is applied to the electrodes to realign liquid crystal molecules of the liquid crystal layer to regulate the transmittance of light passing through the liquid crystal layer.

A thin film transistor (TFT) display panel is used to drive pixels in the LCD or an organic electroluminescent (EL) display device. The thin film transistor array panel includes a signal wire or a gate wire transmitting a scanning signal, an image signal line or a data wire transmitting an image signal, a thin film transistor connected to the gate wire and the data wire, a pixel electrode connected to the thin film transistor, a gate insulating layer covering the gate wire for insulating, and an interlayer insulating layer covering the thin film transistor and the data wire.

To manufacture the thin film transistor array panel including a plurality of layers, a photosensitive film is formed for every layer and the thin film is etched by using the photosensitive film as a mask to form the pattern of each layer.

The total number of processes used during the manufacturing of the thin film transistor array can be reduced by etching the plurality of thin films using one photosensitive film. However, since the data wire and the ohmic contact are made of different materials, the data wire is wet-etched and the ohmic contact is dry-etched, which increases the time spent on patterning and increases the overall complexity of the manufacturing process.

### SUMMARY OF THE INVENTION

A method for manufacturing a thin film transistor array panel according to an exemplary embodiment of the invention includes forming a photosensitive film pattern on a metal layer on a substrate, etching upper and lower layers of the metal layer corresponding to a third section by using the photosensitive film pattern as a mask to form a first metal pattern and a second metal pattern, etching the photosensitive film pattern to remove a first part, etching a first amorphous silicon layer and a second amorphous silicon layer corresponding to the third section by using a second part of the film pattern as a mask to form an amorphous silicon pattern and a semiconductor, and etching the first metal pattern and the second metal pattern of a region corresponding to a first section by using the second part as a mask to form a source electrode and a drain electrode including an upper layer and a lower layer, and etching the amorphous silicon pattern of the region corresponding to the first section by using the second part as a mask to form an ohmic contact. The film pattern includes the first part in the first section and the second part in a second section that is thicker than the first part. The metal layer is exposed in the third section.

A thin film transistor array panel according to at least embodiment of the invention is capable of simultaneously etching a data wire and an ohmic contact by using one etchant.

A method for manufacturing a thin film transistor array panel according to an exemplary embodiment of the present invention includes forming a gate electrode on an insulation substrate, forming a gate insulating layer on the gate electrode, forming a first amorphous silicon layer, a second amorphous silicon layer, a first metal layer, and a second metal layer on the gate insulating layer, forming a photosensitive film pattern on the second metal layer, wherein the pattern includes a first part in a first section of the panel and a second part in a second section of the panel that is thicker than the first part such that the second metal layer is exposed in a third section of the panel, etching the second metal layer and the first metal layer of a region corresponding to the third section by using the photosensitive film pattern as a mask to form a second metal pattern and a first metal pattern, etching the photosensitive film pattern to remove the first part, etching the second amorphous silicon layer and the first amorphous silicon layer corresponding to the third portion by using the second part as a mask to form an amorphous silicon pattern and a semiconductor, etching the second metal pattern and the first metal pattern of a region corresponding to the first section by using the second part as a mask to form a source electrode and a drain electrode including an upper layer and a lower layer, and etching the amorphous silicon pattern of the region corresponding to the first section by using the second part as a mask to form an ohmic contact.

The forming of the source electrode, the drain electrode, and the ohmic contact may be executed through wet etching using an etchant including a fluoride-based compound.

The fluoride-based compound may include at least one of HF, ABF, FBA, and AF. The etchant may include ammonium persulfate at a 0.1 wt % to a 50 wt %, an azole-based compound at a 0.01 wt % to a 5 wt %, and a fluoride-based compound including fluorine.

The first metal layer may be made of titanium, and the second metal layer may be made of copper. The first part may be disposed at a position corresponding to a channel portion between the source electrode and the drain electrode.

The method may further include forming a passivation layer having a contact hole exposing the drain electrode on the substrate, and forming a pixel electrode connected to the drain electrode through the contact hole of the passivation layer.

A method for manufacturing a thin film transistor array panel according to an exemplary embodiment of the invention includes forming a gate electrode on an insulation substrate, forming a gate insulating layer on the gate electrode, forming a first amorphous silicon layer, a second amorphous silicon layer, a first metal layer, and a second metal layer on the gate insulating layer, forming a photosensitive film pattern on the second metal layer, wherein the pattern includes a first part in a first section of the panel and a second part in a second section of the panel that is thicker than the first part such that the second metal layer is exposed in a third section of the panel, etching the second metal layer of a region corresponding to the third section by using the photosensitive film pattern as a mask to form a metal pattern, etching the photosensitive film pattern to remove the first part, etching the second metal layer and the first metal layer of a region corresponding to the first and third section by using the second part as a mask to form a source electrode and a drain electrode including an upper layer and a lower layer, and etching the second amorphous silicon layer and the first amorphous silicon layer of the region corresponding to the first and third sections by using the second part as a mask to form an amorphous silicon pattern and a semiconductor.

The etching of the second metal layer may be executed through wet etching using an etchant including a fluoride-based compound. The etching of the metal layers and amorphous layers of the first and third sections may be continuously executed.

In the etching of the metal layers and amorphous silicon layers, the second metal pattern, the first metal layer, and the second amorphous silicon layer may be continuously etched in the region corresponding to the first section, and the first metal layer, the second amorphous silicon layer, and the first amorphous silicon layer may be continuously etched in the region corresponding to the third section. The etching of the second metal layer of the region corresponding to the third section may use an etchant having a large etching selectivity for the first metal layer and the second metal layer.

The fluoride-based compound may include at least one of HF, ABF, FBA, and AF. The first metal layer may be made of titanium, and the second metal layer may be made of copper. The etchant may include ammonium persulfate at a 0.1 wt % to a 50 wt %, an azole-based compound at a 0.01 wt % to a 5 wt %, and a fluoride-based compound including fluorine.

The method may further include forming a passivation layer having a contact hole exposing the drain electrode on the substrate, and forming a pixel electrode connected to the drain electrode through the contact hole in the passivation layer.

A method for manufacturing a thin film transistor array panel according to an exemplary embodiment of the invention includes forming a gate electrode on an insulation substrate, forming a gate insulating layer on the gate electrode, forming a first amorphous silicon layer, a second amorphous silicon layer, a first metal layer, and a second metal layer on the gate insulating layer, forming a photosensitive film pattern on the second metal layer, wherein the pattern includes a first part in a first section of the panel and a second part in a second section of the panel that is thicker than the first part such that the second metal layer is exposed in a third section of the panel, etching the second metal layer of a region corresponding to the third section by using the photosensitive film pattern as a mask to form a metal pattern, etching the photosensitive film pattern to remove the first part, etching the second metal layer and the first metal layer of a region corresponding to the first and third sections by using the second part as a mask to form a source electrode and a drain electrode including an upper layer and a lower layer, etching the second amorphous silicon layer and the first amorphous silicon layer of the region corresponding to the third section by using the second part as a mask to form an amorphous silicon pattern and a semiconductor pattern at the same time with the etching of the second metal layer and the first metal layer, and etching the amorphous silicon pattern or semiconductor pattern of a region corresponding to the first and third sections by using the second part as a mask to form an ohmic contact and a semiconductor.

The etching of the metal layers and the amorphous silicon layers may be executed through wet etching using an etchant including a fluoride-based compound. The etching of the amorphous silicon pattern or the semiconductor pattern may be executed through dry etching. The etching of the second metal layer of the region corresponding to the third section may use an etchant having a large etching selectivity for the first metal layer and the second metal layer.

The amorphous silicon pattern may be etched in a channel portion where the first portion is positioned, and the semiconductor pattern may be etched in the remaining portion where the photosensitive film pattern is absent.

The fluoride-based compound may include at least one of HF, ABF, FBA, and AF. The first metal layer may be made of titanium, and the second metal layer may be made of copper. The etchant may include ammonium persulfate at a 0.1 wt % to a 50 wt %, an azole-based compound at a 0.01 wt % to a 5 wt %, and a fluoride-based compound including fluorine.

The method may further include forming a passivation layer having a contact hole exposing the drain electrode on the substrate, and forming a pixel electrode connected to the drain electrode through the contact hole in the passivation layer.

According to at least one exemplary embodiment of the present invention, a data wire and an ohmic contact are wet-etched together such that the manufacturing process of the thin film transistor array panel may be simplified and the process time may be reduced.

### BRIEF DESCRIPTION OF THE DRAWINGS

FIG. 1 is a layout view of a pixel of a thin film transistor array panel according to at least one embodiment of the present invention.

FIG. 2 is a cross-sectional view taken along line II-II of FIG. 1.

FIGS. 3 to 7 are cross-sectional views sequentially showing a method of manufacturing a thin film transistor array panel according to an exemplary embodiment of the present invention and taken along the line II-II of FIG. 1.

FIGS. 8 to 10 are cross-sectional views sequentially showing a method of manufacturing a thin film transistor array panel according to an exemplary embodiment of the present invention and taken along line VIII-VIII of FIG. 1.

FIGS. 11 to 14 are cross-sectional views sequentially showing a method of manufacturing a thin film transistor array panel according to an exemplary embodiment of the present invention and taken along the line VIII-VIII of FIG. 1.

### DETAILED DESCRIPTION OF EXEMPLARY EMBODIMENTS

The present invention will be described more fully hereinafter with reference to the accompanying drawings, in which exemplary embodiments of the invention are shown. In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or intervening elements may also be present.

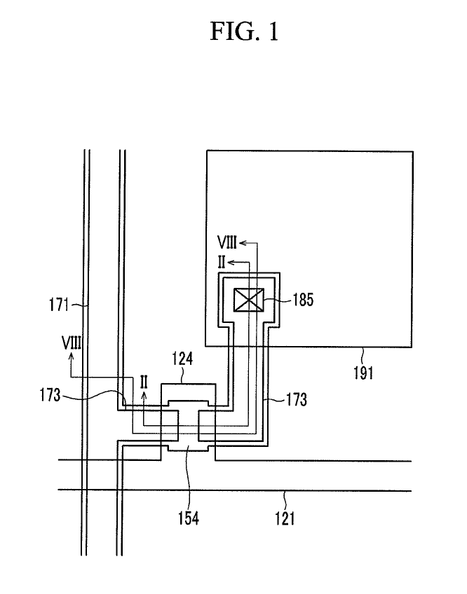

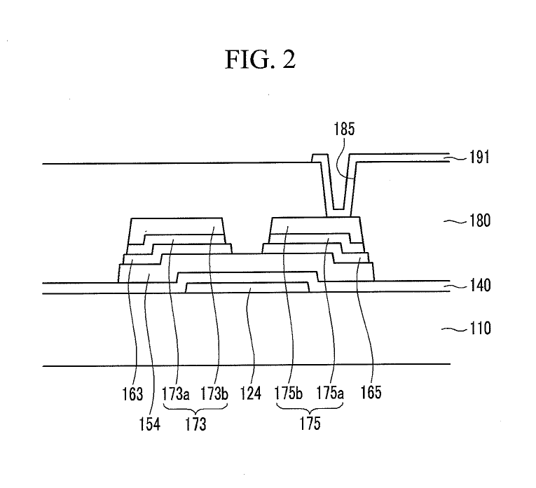

FIG. 1 is a layout view of a pixel of a thin film transistor array panel according to an exemplary embodiment of the present invention, and FIG. 2 is a cross-sectional view taken along line II-II of FIG. 1. Referring to FIG. 1 and FIG. 2, a gate line 121 is formed on an insulating substrate 110. The insulating substrate 110 may be made of transparent glass or plastic as an example. The gate line 121 transmits a gate signal and mainly extends in a first direction. The gate line 121 includes gate electrodes 124 that protrude from the gate line 121, and an end portion having a wide area for connection with another layer or an external driving circuit.

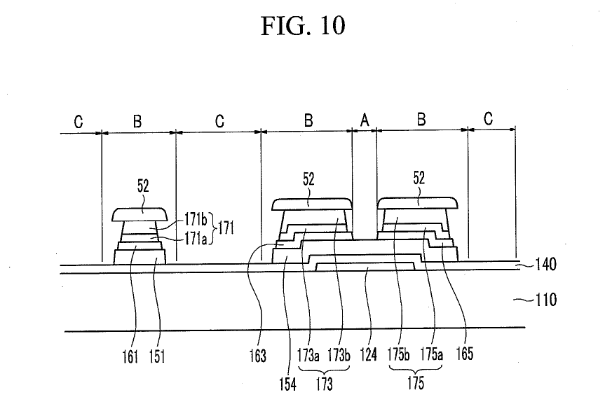

A gate insulating layer 140 is formed on the gate line 121. The gate insulating layer 140 may be made of silicon nitride as an example. A plurality of semiconductor stripes 151 (e.g., shown in FIG. 10) may be formed on the gate insulating layer 140. The semiconductor stripes 151 may be made of hydrogenated amorphous silicon or polysilicon as an example. The semiconductor stripes 151 extend in a second direction different from first direction and include projections 154 that protrude toward the gate electrode 124.

Ohmic contact stripes (not shown) and ohmic contact islands 165 are formed on the projections 154. The ohmic contact stripes include projections 163, and the projections 163 and ohmic contact islands 165 are disposed as a pair on the projections 154 of the semiconductor stripes 151.

A data line 171 and a drain electrode 175 are formed on the ohmic contacts 163 and 165 and the gate insulating layer 140. The data line 171 for transmitting a data signal mainly extends in the second direction and intersects the gate line 121. The data line 171 includes a source electrode 173 extending toward the gate electrode 124 and an end portion having a wide area for connection with the other layer or the external driving circuit. The drain electrode 175 is separated from the data line 171 and faces the source electrode 173 with reference to the gate electrode 124.

The data line 171, the source electrode 173, and the drain electrode 175 may each be made of two layers. The data line 171 may include an upper layer 171b and a lower layer 171a (e.g., shown in FIG. 10). The source electrode 173 may include an upper layer 173b and a lower layer 173a, and the drain electrode may include an upper layer 175b and a lower layer 175a. The upper layers 171b, 173b, and 175b may be made of a metal with a low resistivity such as copper as an example. The lower layers 171a, 173a, and 175a may be made of a metal having an excellent contact characteristic such as titanium as an example.

One gate electrode 124, one source electrode 173, and one drain electrode 175 form a thin film transistor (TFT) along with a projection 154 of the semiconductor, and the channel of the thin film transistor is formed in the projection 154 between the source electrode 173 and the drain electrode 175.

In an exemplary embodiment of the invention, the ohmic contacts 163 and 165 are interposed only between the underlying semiconductor islands 154 and the overlying data lines 171 and drain electrodes 175, and may reduce contact resistance therebetween. The projections 154 of the semiconductor may include a portion between the source electrodes 173 and the drain electrodes 175, and portions exposed by the data lines 171 and the drain electrodes 175.

The semiconductor stripe 151 except for the exposed portion of the projection 154 may have substantially the same plane shape as the ohmic contacts 163 and 165, and the ohmic contacts 163 and 165 may have substantially the same plane shape as the data lines 171 and the drain electrodes 175. The similarity in shape may occur when the data lines 171 and drain electrodes 175, the semiconductors 154, and the ohmic contacts 163 and 165 are formed using a photosensitive film pattern having different thicknesses, which will be described below through a manufacturing method.

A passivation layer 180 is formed on the data lines 171, the drain electrodes 175, and the exposed semiconductors 154. The passivation layer 180 may be made of an inorganic insulator such as silicon nitride or silicon oxide, an organic insulator, or an insulator having a low dielectric constant. The passivation layer 180 has a contact hole 185 exposing the drain electrode 175.

A plurality of pixel electrodes 191 are formed on the passivation layer 180. The pixel electrodes 191 are electrically and physically connected to the drain electrodes 175 through the contact holes 185 to receive the data voltages from the drain electrodes 175. The pixel electrodes 191 to which a data voltage is applied and a common electrode (not shown) of another display panel (not shown) that receives a common voltage generate an electric field, thereby adjusting a direction of liquid crystal molecules of a liquid crystal layer (not shown) between the two electrodes. The pixel electrodes 191 and the common electrode form a capacitor (hereinafter referred to as a “liquid crystal capacitor”) through which an applied voltage is sustained even after a thin film transistor is turned off.

The pixel electrode 191 and a storage electrode line (not shown) overlap each other thereby forming a storage capacitor that enhances the capacity for maintaining the voltage of the liquid crystal capacitor.

The pixel electrode 191 may be made of a transparent conductive material such as ITO or IZO, or a metal having excellent reflectance.

A method of manufacturing a thin film transistor array panel shown in FIG. 1 and FIG. 2 according to an exemplary embodiment of the present invention will be described with reference to FIGS. 2-8.

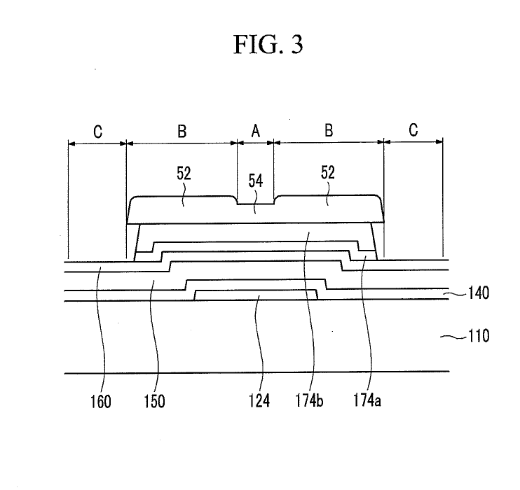

FIGS. 3-8 are cross-sectional views sequentially showing a method of manufacturing a thin film transistor array panel according to an exemplary embodiment of the present invention, taken along the line II-II shown in FIG. 1.

As shown in FIG. 3, a metal layer is deposited on an insulation substrate 110, and the metal layer is patterned to form a gate line including gate electrodes 124. As discussed above, the insulation substrate 110 may be made of transparent glass or plastic as an example.

Next, a gate insulating layer 140, a first amorphous silicon layer 150, a second amorphous silicon layer 160, a first conductive layer, and a second conductive layer are deposited on the gate electrode 124. The second amorphous silicon layer 160 may be doped with a conductive impurity. The first conductive layer may be formed of titanium as an example, and the second conductive layer may be made of copper as an example.

A photosensitive film is coated on the second conductive layer, and is exposed and developed to form photosensitive film patterns 52 and 54 having different thicknesses depending on position. The thickness of pattern 54 may be less than the thickness of the majority of a pattern 52. Portions of the gate insulating layer 140, the first and second conductive metal layers, the first amorphous silicon layer 150, and the second amorphous silicon layer 160 corresponding to the channel of the TFT are referred to as a channel portion A. Portions of the gate insulating layer 140, the first amorphous silicon layer 150, the second amorphous silicon layer 160, the first metal layer, and the second metal layer corresponding to the source electrode 173 and the drain electrode 175 are referred to as a wiring portion B, and the portion except for the wiring portion B and the channel portion A is referred to as a remaining portion C.

Among the photosensitive film patterns 52 and 54, the photosensitive film pattern 52 corresponding to the wiring portion B is thicker than the photosensitive film pattern 54 corresponding to the channel portion A, and the photosensitive film is removed on the remaining portion C. In this example, the thickness ratio of the photosensitive film pattern 52 corresponding to the wiring portion B and the photosensitive film pattern 54 corresponding to the channel portion A may vary depending on etching process conditions. In an exemplary embodiment of the invention, the thickness of the photosensitive film pattern 54 is half the thickness of the photosensitive film pattern 52.

The photosensitive patterns may be formed such that portions thereof have different thicknesses according to their positions, for example, by using an exposure mask including a transparent area, a light blocking area, and a semi-transparent area. The semi-transparent area may include a slit pattern, a lattice pattern, or a thin film having median transmittance or having a median thickness. When the slit pattern is used, the width of the slits or the space between the slits may be smaller than a resolution of a light exposer used for photolithography. The photosensitive patterns may be formed using a reflowable photosensitive film. For example, a thin portion of a photosensitive pattern may be foamed by making a photosensitive film flow into a region where the photosensitive film is not present after forming the reflowable photosensitive film with a general exposure mask having only a light transmitting area and a light blocking area.

Next, the second metal layer and the first metal layer of the remaining region C are etched by using the photosensitive film patterns 52 and 54 as an etch mask to form a second metal pattern 174b and a first metal pattern 174a.

The etching may be executed through wet etching such that an undercut may be formed under the photosensitive film pattern.

Next, a pre-treatment may be executed to prevent the side of the exposed second metal pattern 174b from being corroded. The pre-treatment may be executed by using Oxygen (O₂) gas, a mixture of Sulfur Hexafluoride (SF₆) gas and O₂ gas, SF₆ gas, or a mixture of SF₆ gas and Helium (He) for a period of time (e.g., about 10 seconds).

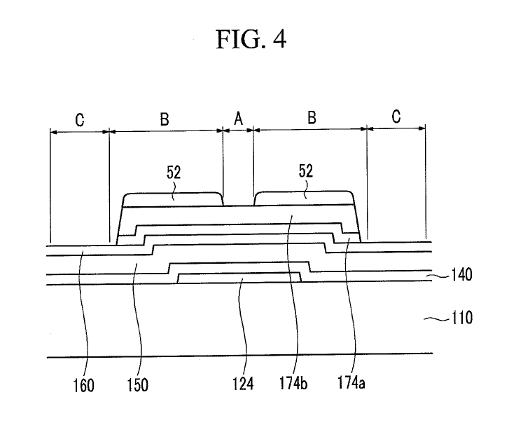

Next, as shown in FIG. 4, the photosensitive film pattern 54 of the channel portion is removed through an etch-back process. The pattern 54 is removed entirely and the photosensitive film patterns 52 are reduced in thickness and width.

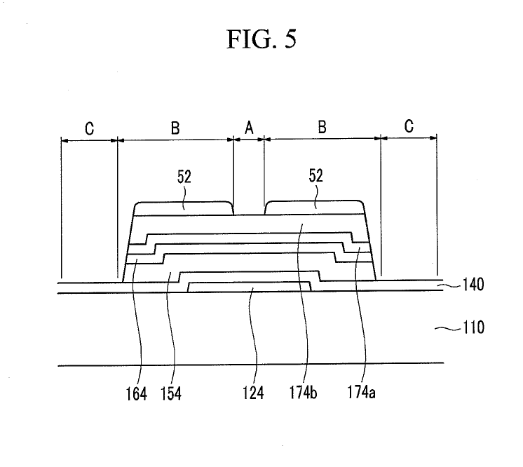

Next, as shown in FIG. 5, the second amorphous silicon layer and the first amorphous silicon layer are etched by using the photosensitive film pattern 52 as an etch mask to form an amorphous silicon pattern 164 and a semiconductor 154.

The second amorphous silicon layer and the first amorphous silicon layer may be etched to form the amorphous silicon pattern 164 and the semiconductor 154 before the etch-back process. However, the portion of the photosensitive film pattern may be removed during the etch-back process, and if the amorphous silicon layer is etched after the etch-back process, the amorphous silicon layer is etched by the photosensitive film pattern that was previously removed as the mask such that the semiconductor may protrude outside the boundary of the first metal pattern. For example, if the amorphous silicon layer is etched after the etch-back process, the semiconductor may protrude outside the metal pattern by the undercut formed between the photosensitive film pattern and the metal pattern. However if the portion of the photosensitive film pattern is removed through the etch-back process, the size of the undercut is reduced such that the width that the semiconductor protrudes outside the metal pattern may be reduced.

Next, a post-treatment may be executed to remove impurities generated during the etch-back process and the etching of the amorphous silicon layer. The post-treatment process may use the mixed gas of SF₆ and O₂ or the mixed gas of O₂ and He for about a period of time (e.g., about 10 seconds).

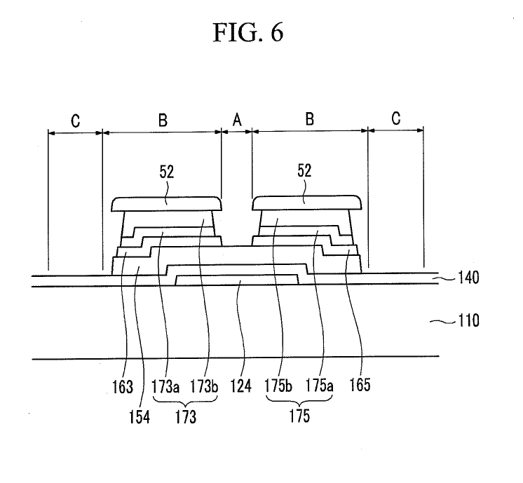

Next, as shown in FIG. 6, the second metal pattern 174b, the first metal pattern 174a, and the amorphous silicon pattern 164 are wet-etched by using the photosensitive film pattern 52 as an etch mask to foam a source electrode 173 and a drain electrode 175 including upper layers 173b and 175b and lower layers 173a and 175a, and ohmic contacts 163 and 165. Based on the thickness of the pattern, it may take between about 30 seconds to about 70 seconds to etch the second metal pattern 174b and the first metal pattern 174a. However, embodiments of invention are not limited thereto, as the metal pattern etching could take less than 30 seconds or more than 70 seconds in alternate embodiments. It may take about 20 second to about 30 seconds to etch the second amorphous silicon layer after the etching of the metal pattern. However, embodiments of invention are not limited thereto, as the amorphous silicon layer etching could take less than 20 seconds or more than 30 seconds in alternate embodiments. When etching the second amorphous silicon layer, a portion of the semiconductor may be etched. Here, the etchant may include fluorine (F) ions. For example, the etchant may include at least one additive of hydrogen fluoride (HF), ammonium fluoride (AF), ammonium fluoride (NH₄F), fluoroboric acid (FBA), or ammonium bifluoride (ABF) based on peroxide (H₂O₂), or may basically include at least one of HF, FBA, ABF, and AF.

The etchant may include ammonium persulfate ((NH4)2S2O8) at a range of between a 0.1 weight percent (wt %) to a 50 wt %, an azole-based compound at a range of between a 0.01 wt % to a 5 wt %, and a fluoride-based compound including fluorine at a range of between a 0.05 wt % to a 1 wt %.

The etch ratio of the fluoride-based compound for titanium and amorphous silicon layer is changed according to the ratio of the included F, and when the etch ratio of HF is 100%, FBA has a ratio of 50%, ABF has a ratio of 30%, and AF has a ratio of 8%. Accordingly, when using FBA, ABF, or AF, the etch ratio may be adjusted by increasing the concentration of F based on HF.

In an exemplary embodiment of the present invention, the etchant including the fluoride-based compound including fluorine may be used to etch the data wire and the ohmic contact together. The etchant including the fluoride-based compound including fluorine may be used to etch the first metal layer and the second metal layer of FIG. 3.

If photosensitive film patterns having different thickness are used, the data line 171 including the source electrode 173 and the drain electrode 175 may have substantially the same plane pattern as the ohmic contact stripe having the projections and the ohmic contact island 165. Further, the semiconductor having the projection 154 except for the exposed portion between the drain electrode 175 and the source electrode 173 may have substantially the same plane pattern as the data lines 171 including the source electrode 173 and the drain electrode 175.

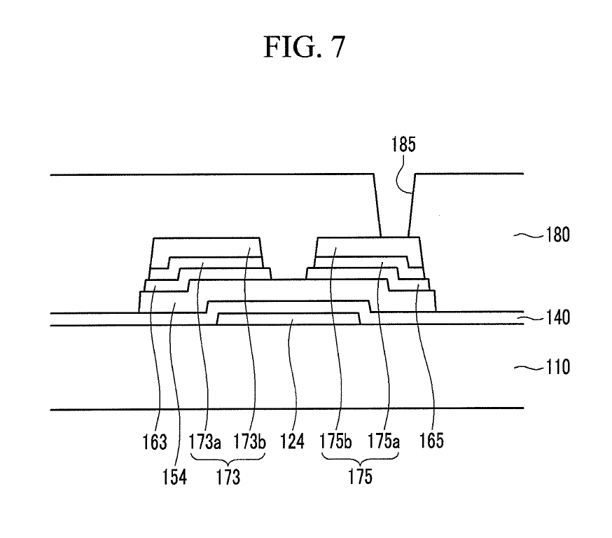

A passivation layer 180 shown in FIG. 7 covering the exposed portion of the projection 154 of the semiconductor may be formed and patterned by photolithography to form a contact hole 185 exposing the upper layer 175b of the drain electrode 175.

Next, as shown in FIG. 2, a pixel electrode 191 connected to the drain electrode 175 through the contact hole 185 is formed on the passivation layer 180.

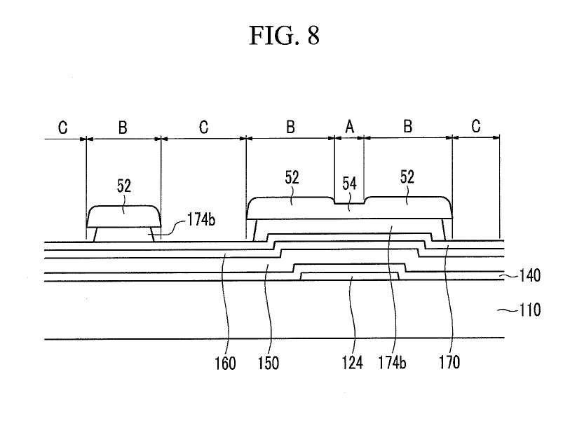

A method of manufacturing a thin film transistor array panel according to another exemplary embodiment of the present invention will be described with reference to FIG. 8 to FIG. 10.

FIGS. 8 to 10 are cross-sectional views sequentially showing a method of manufacturing method a thin film transistor array panel according to another exemplary embodiment of the present invention, taken along the line VIII-VIII shown in FIG. 1.

As shown in FIG. 8, a metal layer is deposited on an insulation substrate 110 is patterned to form a gate line including gate electrodes 124. As discussed above, the insulation substrate 110 may be made of transparent glass or plastic.

Next, a gate insulating layer 140, a first amorphous silicon layer 150, a second amorphous silicon layer 160, a first conductive layer 170, and a second conductive layer are deposited on the gate electrode 124. The second amorphous silicon layer 160 may be doped with a conductive impurity. As an example, the first conductive layer 170 may be formed of titanium and the second conductive layer may be made of copper.

Next, a photosensitive film is coated on the second conductive layer, and is exposed and developed to form photosensitive film patterns 52 and 54 having different thicknesses depending on position. The photosensitive film patterns 52 and 54 having different thicknesses may be formed with the same method as the method of FIG. 3, and the photosensitive film patterns 52 and 54 include the channel portion A, the wiring portion B, and the remaining portion C, as also shown in FIG. 3.

Next, the second metal layer of the remaining portion C is etched by using the photosensitive film pattern 52 and 54 as an etch mask to form the second metal pattern 174b. Here, an undercut may be formed under the photosensitive film pattern by wet etching.

The etching may be executed by the first etchant having large etching selectivity for the first metal layer and the second metal layer. For example, the first etchant including APS at about a 12 wt %, nitric acid at about a 3 wt %, and an organic acid at about a 4-5 wt % may be used.

Next, a pre-treatment may be executed to prevent the side of the exposed second metal pattern 174b from being corroded, as also shown in FIG. 3.

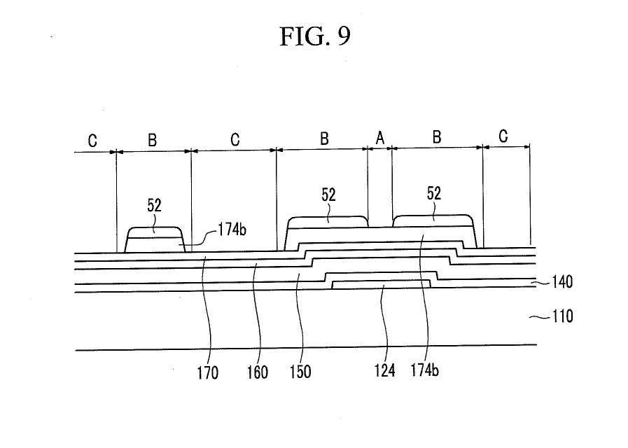

Next, as shown in FIG. 9, the photosensitive film pattern 54 of the channel portion is removed through an etch-back process. Here, the pattern 54 is entirely removed and the photosensitive film patterns 52 are reduced in thickness and width.

Next, as shown in FIG. 10, the second metal pattern and the first metal layer of the channel portion A and the first metal layer of the remaining portion C are etched by using the second etchant and the photosensitive film pattern 52 as the etch mask to form the data line 171, the source electrode 173, and the drain electrode 175. As discussed above, the data line 171 includes an upper layer 171b and lower layer 171a, the source electrode 173 include an upper layer 173b and a lower layer 173a, and the drain electrode 175 includes an upper layer 175b and a lower layer 175a. The etching also forms the second amorphous silicon layer, the first amorphous silicon layer of the channel portion A, and the remaining portion C to form ohmic contacts 161, 163, and 165 and the semiconductors 151 and 154. The ohmic contact stripe 161 and the semiconductor stripe 151 are disposed under the data line 171.

The second etchant used in FIG. 6 may include fluorine (F) ions. For example, the second etchant may include at least one additive of hydrogen fluoride (HF), ammonium fluoride (AF), ammonium fluoride (NH₄F), fluoroboric acid (FBA), ammonium bifluoride (ABF) based on peroxide (H₂O₂), or may basically include at least one of HF, FBA, ABF, and AF.

For example, the second etchant may include ammonium persulfate ((NH₄)₂S₂O₈) at a range between a 0.1 wt % to a 50 wt %, an azole-based compound at a range of a 0.01 wt % to a 5 wt %, and a fluoride-based compound including fluorine at a range of a 0.05 wt % to a 1 wt %.

Further, the second etchant including APS at about a 12 wt %, nitric acid at about a 2 wt %, organic acid at about a 1 wt %, NH₄F at about a 1 wt %, and FBA at about a 0.7 wt % may be used.

The etch ratio of the fluoride-based compound for titanium and amorphous silicon layer is changed according to the ratio of the included F, and when the etch ratio of HF is 100%, FBA has a ratio of 50%, ABF has a ratio of 30%, and AF has a ratio of 8%. Accordingly, when using FBA, ABF, and AF, the etch ratio may be adjusted by increasing the concentration of F based on HF.

The etch ratio of the first metal layer may be controlled to be larger than that of the second metal layer in an exemplary embodiment of the invention. For example, if the etch ratio of the first metal layer is larger than the etch ratio of the second metal layer, the first amorphous silicon layer of the channel portion A may remain while the first metal layer, the second amorphous silicon layer, and the first amorphous silicon layer of the remaining portion C are completely removed.

Alternately, the second amorphous silicon layer of the channel portion A may be completely removed such that the over-etch is executed for the second amorphous silicon layer positioned at the channel portion A to be removed. Accordingly, the upper portion of the first amorphous silicon layer under the second amorphous silicon layer positioned at the channel portion A may be removed.

In the exemplary embodiment of the present invention, the etchant including the fluoride-based compound including fluorine may be used to simultaneously etch the data wire and the ohmic contact, like the exemplary embodiment of FIG. 1 to FIG. 7.

However, if the first metal layer, the second metal layer, the first amorphous silicon layer, and the second amorphous silicon layer are simultaneously etched through the wet etching of FIG. 3, the etch time may be increased and the slope of the etched side may be decreased such that the slope of the inclined surface is elongated. If the slope of the side is decreased, the cover characteristic of the upper layer is improved when forming the upper layer. However, as shown in FIG. 6, the first metal layer and the second metal layer are over-etched when the wet etching is additionally executed such that the width may be decreased more than the desired width of the wiring.

Accordingly, after the etching to form the second metal pattern is executed as in FIGS. 8 to 11 according to an exemplary embodiment of the present invention, the first metal layer, the first amorphous silicon layer, and the second amorphous silicon layer are etched such that the reduction of the wiring width may be further decreased compared with the exemplary embodiment of FIGS. 1 to 7.

A passivation layer 180 covering the exposed portion of the projection 154 of the semiconductor as shown in FIG. 2 may be formed and patterned by photolithography to form a contact hole 185 exposing the upper layer 175b of the drain electrode 175. Then, a pixel electrode 191 connected to the drain electrode 175 through the contact hole 185 is formed on the passivation layer 180.

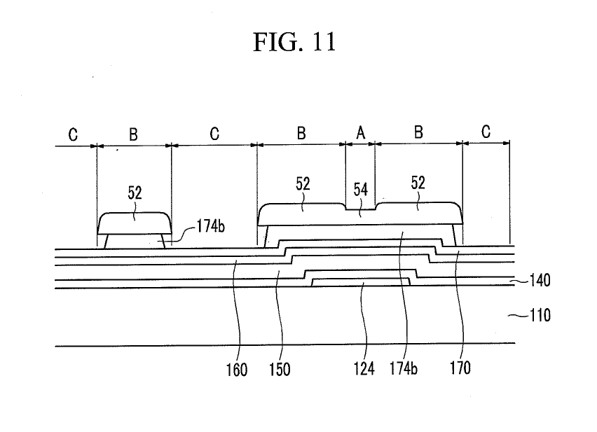

A method of manufacturing a thin film transistor array panel according to another exemplary embodiment of the present invention will be described with reference to FIG. 11 to FIG. 14.

FIGS. 11 to 14 are cross-sectional views sequentially showing a method of manufacturing a thin film transistor array panel according to another exemplary embodiment of the present invention, taken along the line VIII-VIII shown in FIG. 1.

As shown in FIG. 11, a metal layer is deposited on an insulation substrate 110 and is patterned to form a gate line including gate electrodes 124. As discussed above, the insulation substrate 110 may be made of transparent glass or plastic.

Next, a gate insulating layer 140, a first amorphous silicon layer 150, a second amorphous silicon layer 160, a first conductive layer 170, and a second conductive layer are deposited on the gate electrode 124. The second amorphous silicon layer 160 may be doped with a conductive impurity. As an example, the first conductive layer 170 may be formed of titanium, and the second conductive layer may be made of copper.

Next, a photosensitive film is coated on the second conductive layer, and is exposed and developed to form photosensitive film patterns 52 and 54 having different thicknesses depending on position. The photosensitive film patterns 52 and 54 having different thicknesses may be formed with the same method as the method of FIG. 3, and the photosensitive film patterns 52 and 54 includes the channel portion A, the wiring portion B, and the remaining portion C, as also shown in FIG. 3.

Next, the second metal layer of the remaining portion C is etched using the photosensitive film pattern 52 and 54 as the etch mask to form the second metal pattern 174b. Here, the undercut may be formed under the photosensitive film pattern by wet etching. The etching may be executed by an etchant having a large etching selectivity for the first metal layer and the second metal layer. For example, the etchant described with respect to FIG. 8 may be used.

Next, a pre-treatment may be executed to prevent the side of the exposed second metal pattern 174b shown in FIG. 3 from being corroded.

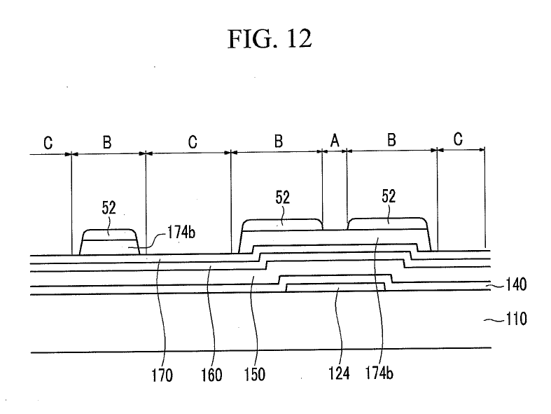

Next, as shown in FIG. 12, the photosensitive film pattern 54 of the channel portion is removed through an etch-back process. Here, the pattern 54 is entirely removed and a thickness and width of the photosensitive film patterns 52 are reduced.

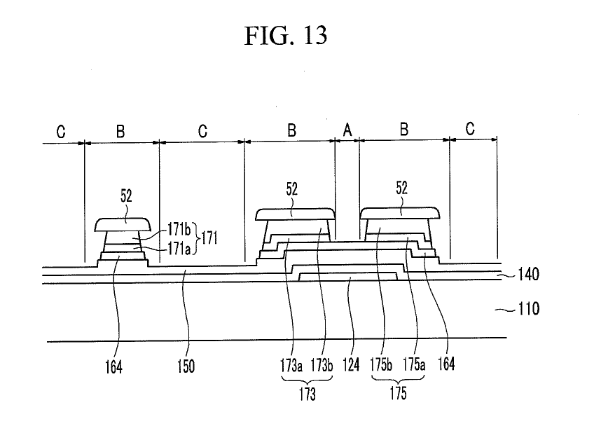

Next, as shown in FIG. 13, the second metal pattern and the first metal layer of the channel portion A and the first metal layer of the remaining portion C are etched by using the photosensitive film pattern 52 as the etch mask to form the data line 171 including the source electrode 173 and the drain electrode 175 made of upper layers 171b, 173b, and 175b and lower layers 171a, 173a, and 175a. Also, the second amorphous silicon layer of the remaining portion C is etched together therewith to form the amorphous silicon pattern 164.

Here, the upper portion of the first amorphous silicon layer 150 of the remaining portion C may be partially removed. The thickness of the remaining first amorphous silicon layer 150 may be equal to or thinner than the thickness of the amorphous silicon pattern 164.

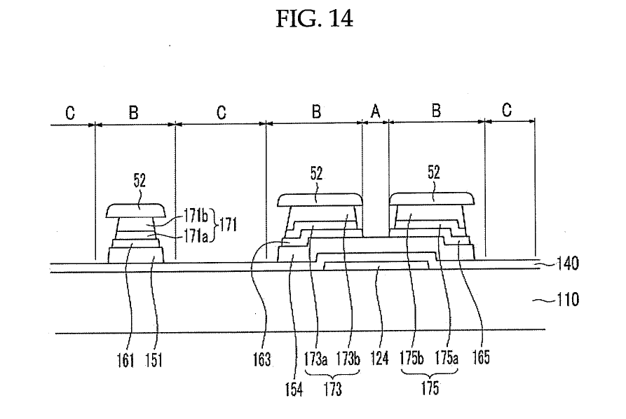

Next, as shown in FIG. 14, the second amorphous silicon layer of the channel portion A and the remaining first amorphous silicon layer of the remaining portion C are removed by the dry etching to complete the ohmic contacts 161, 163, and 165 and the semiconductor 154.

As shown in FIG. 13, the thickness of the remaining first amorphous silicon layer is equal to or thinner than the thickness of the amorphous silicon pattern. In at least one embodiment of the invention, the first amorphous silicon layer of the channel portion A is not removed during the time that the first amorphous silicon layer of the remaining portion C is removed.

Over-etching may be executed to completely remove the amorphous silicon pattern of the channel portion A, and here, the upper portion of the first amorphous silicon layer may be removed.

Alternately, if the channel portion A is dry-etched like an exemplary embodiment of the present invention, the formation of the undercut that may be generated under the wet etching may be minimized, differently from the exemplary embodiment of FIG. 8.

A passivation layer 180 covering the exposed portion of the projection 154 of the semiconductor as shown in FIG. 2 may be formed and patterned by photolithography to form a contact hole 185 exposing the upper layer 175b of the drain electrode 175.

Next, a pixel electrode 191 connected to the drain electrode 175 through the contact hole 185 is formed on the passivation layer 180.

Having described exemplary embodiments of the present invention, it is to be understood that the invention is not limited to the disclosed embodiments, but, on the contrary, is intended to cover various modifications and equivalent arrangements included within the spirit and scope of the disclosure.

What is claimed is:

1. A method for manufacturing a thin film transistor array panel, comprising:
forming a gate electrode on an insulation substrate;
forming a gate insulating layer on the gate electrode;
forming a first amorphous silicon layer on the gate insulating layer;
forming a second amorphous silicon layer on the first amorphous silicon layer;
forming a first metal layer on the second amorphous silicon layer;
forming a second metal layer on the first metal layer;
forming a photosensitive film pattern on the second metal layer, wherein the film pattern includes a first part in a first section of the panel and a second part in a second section of the panel that is thicker than the first part such that the second metal layer is exposed in a third section of the panel;
etching the second metal layer and the first metal layer of a region corresponding to the third section by using the photosensitive film pattern as a mask to form a second metal pattern and a first metal pattern;
etching the photosensitive film pattern to remove the first part;
etching the second amorphous silicon layer and the first amorphous silicon layer corresponding to the third section by using the second part as a mask to form an amorphous silicon pattern and a semiconductor;
etching the second metal pattern and the first metal pattern of a region corresponding to the first section by using the second part as a mask to form a source electrode and a drain electrode including an upper layer and a lower layer; and
etching the amorphous silicon pattern of the region corresponding to the first section by using the second part as a mask to form an ohmic contact.

2. The method of claim 1, wherein the forming of the source electrode, the drain electrode, and the ohmic contact are executed through wet etching using an etchant including a fluoride-based compound.

3. The method of claim 2, wherein the fluoride-based compound includes at least one of hydrogen fluoride, ammonium bifluoride, fluoroboric acid, and ammonium fluoride.

4. The method of claim 3, wherein the etchant includes ammonium persulfate between a 0.1 weight percent and a 50 weight percent, an azole-based compound between a 0.01 weight percent and 5 weight percent, and a fluoride-based compound including fluorine.

5. The method of claim 1, wherein the first metal layer is made of titanium, and the second metal layer is made of copper.

6. The method of claim 1, wherein the first part is located at a position corresponding to a channel portion between the source electrode and the drain electrode.

7. The method of claim 1, further comprising:
forming a passivation layer having a contact hole exposing the drain electrode on the substrate; and
forming a pixel electrode connected to the drain electrode through the contact hole of the passivation layer.

8. A method for manufacturing a thin film transistor array panel, comprising:
forming a gate electrode on an insulation substrate;
forming a gate insulating layer on the gate electrode;
forming a first amorphous silicon layer on the gate insulating layer;
forming a second amorphous silicon layer on the first amorphous silicon layer;
forming a first metal layer on the gate insulating layer;
forming a second metal layer on the first metal layer;
forming a photosensitive film pattern on the second metal layer, wherein the pattern includes a first part in a first section of the panel and a second part in a second section of the panel that is thicker than the first part such that the second metal layer is exposed in a third section of the panel;
etching the second metal layer of a region corresponding to the third section by using the photosensitive film pattern as a mask to form a metal pattern;
etching the photosensitive film pattern to remove the first part;
etching the second metal layer and the first metal layer of a region corresponding to the first section and the third section by using the second part as a mask to form a source electrode and a drain electrode including an upper layer and a lower layer; and
etching the second amorphous silicon layer and the first amorphous silicon layer of the region corresponding to the first section and the third section by using the second part as a mask to form an amorphous silicon pattern and a semiconductor.

9. The method of claim 8, wherein the etching of the second metal layer is executed through wet etching using an etchant including a fluoride-based compound.

10. The method of claim 8, wherein the etching of the second metal layer of the region corresponding to the third section uses an etchant having large etching selectivity for the first metal layer and the second metal layer.

11. The method of claim 9, wherein the fluoride-based compound includes at least of hydrogen fluoride, ammonium bifluoride, fluoroboric acid, and ammonium fluoride.

12. The method of claim 8, wherein the first metal layer is made of titanium, and the second metal layer is made of copper.

13. The method of claim 10, wherein the etchant includes ammonium persulfate at a 0.1 weight percent to a 50 weight percent, an azole-based compound at a 0.01 weight percent to a 5 weight percent, and a fluoride-based compound including fluorine.

14. The method of claim 8, further comprising
forming a passivation layer having a contact hole exposing the drain electrode on the substrate, and
forming a pixel electrode connected to the drain electrode through the contact hole on the passivation layer.

15. A method for manufacturing a thin film transistor array panel, comprising:
forming a gate electrode on an insulation substrate;
forming a gate insulating layer on the gate electrode;
forming a first amorphous silicon layer on the gate insulating layer;
forming a second amorphous silicon layer on the first amorphous silicon layer;
forming a first metal layer on the second amorphous silicon layer;
forming a second metal layer on the first metal layer;
forming a photosensitive film pattern on the second metal layer, wherein the pattern includes a first part in a first section of the panel and a second part in a second section of the panel that is thicker than the first part such that the second metal layer is exposed in a third section of the panel;
etching the second metal layer of a region corresponding to the third section by using the photosensitive film pattern as a mask to form a metal pattern;
etching the photosensitive film pattern to remove the first part;
etching the second metal layer and the first metal layer of a region corresponding to the first section and the third section by using the second part as a mask to form a source electrode and a drain electrode including an upper layer and a lower layer;
etching the second amorphous silicon layer and the first amorphous silicon layer of a region corresponding to the third section by using the second part as a mask to form an amorphous silicon pattern and a semiconductor pattern at the same time with the etching of the second metal layer and the first metal layer; and
etching the amorphous silicon pattern or semiconductor pattern of a region corresponding to the first section and the third section by using the second part as a mask to form an ohmic contact and a semiconductor.

16. The method of claim 15, wherein the etching of the first metal layer, the second metal layer, the first amorphous silicon layer, and the second amorphous layer are executed through wet etching using an etchant including a fluoride-based compound, and the etching amorphous silicon pattern or semiconductor pattern is executed through dry etching.

17. The method of claim 15, wherein the etching of the first metal layer and the second metal layer uses an etchant having large etching selectivity for the first metal layer and the second metal layer.

18. The method of claim 15, wherein, in the etching of the amorphous silicon pattern, the amorphous silicon pattern is etched in a channel portion where the first portion is positioned, and in the etching of the semiconductor pattern, the semiconductor pattern is etched in a part of the where the photosensitive film pattern is absent.

19. The method of claim 16, wherein the fluoride-based compound includes at least one of hydrogen fluoride, ammonium bifluoride, fluoroboric acid, and ammonium fluoride.

20. The method of claim 15, wherein the first metal layer is made of titanium, and the second metal layer is made of copper.

21. The method of claim 16, wherein the etchant includes ammonium persulfate at a 0.1 weight percent to a 50 weight percent, an azole-based compound at a 0.01 weight percent to a 5 weight percent, and a fluoride-based compound including fluorine.

22. A method for manufacturing a thin film transistor array panel, comprising:
forming a photosensitive film pattern on a metal layer on a substrate, wherein the pattern includes a first part in a first section of the panel and a second part in a second section of the panel that is thicker than the first part such that the metal layer is exposed in a third section of the panel, and the metal layer has an upper layer and a lower layer;
etching the upper and lower layers corresponding to the third section by using the photosensitive film pattern as a mask to form a first metal pattern and a second metal pattern;
etching the photosensitive film pattern to remove the first part;
etching a first amorphous silicon layer and a second amorphous silicon layer corresponding to the third section by using the second part as a mask to form an amorphous silicon pattern and a semiconductor;
etching the first metal pattern and the second metal pattern of a region corresponding to the first section by using the second part as a mask to form a source electrode and a drain electrode including an upper layer and a lower layer; and
etching the amorphous silicon pattern of the region corresponding to the first section by using the second part as a mask to form an ohmic contact.

23. The method of claim 22, wherein the forming of the source electrode, the drain electrode, and the ohmic contact are executed through wet etching using an etchant including a fluoride-based compound.
